(19) United States
(12) Patent Application Publication
(10) Pub. No.: US 2023/0246622 A1
(43) Pub. Date: Aug. 3, 2023

(54) ELECTRONIC CIRCUIT

(71) Applicant: SONY SEMICONDUCTOR SOLUTIONS CORPORATION, KANAGAWA (JP)

(72) Inventors: SHUN NAGATA, KANAGAWA (JP); MASAHIRO SEGAMI, KANAGAWA (JP)

(21) Appl. No.: 18/004,911

(22) PCT Filed: Jun. 23, 2021
(86) PCT No.: PCT/JP2021/023753

§ 371 Date: Jan. 10, 2023

(30) Foreign Application Priority Data
Jul. 20, 2020 (JP) 2020-123728

(51) Int. Cl. H03H 7/24

(52) U.S. Cl. CPC H03H 7/24

(57) ABSTRACT

[Object]

To suppress distortion of a three-dimensional resistor.

[Solving Means]

The electronic circuit includes a first resistor and a second resistor. The first resistor has a configuration of a resistor for a voltage between a first terminal and a second terminal thereof, and the first terminal is connected directly or indirectly to an input of the electronic circuit. The second resistor has a configuration of a resistor for a voltage between a first terminal and a second terminal thereof, and the first terminal is connected directly or indirectly to the second terminal of the first resistor. In the electronic circuit, the second terminal of the second resistor is connected directly or indirectly to a third terminal through which a resistance value of the first resistor is varied by a voltage.

### TECHNICAL FIELD

The present disclosure relates to an electronic circuit.

### BACKGROUND ART

The resistance value of a resistor of a three-terminal configuration changes depending upon the voltage applied to a sub terminal of the resistor. The change of the resistance value possibly becomes a cause of distortion in an electronic circuit. In this connection, conceivable is a configuration in which an input-dependent correction voltage is applied to the sub terminal of the resistor on the input side to make it possible to cancel the voltage dependency of the resistor according to the resistance ratio. However, this scheme is effective only in a configuration that uses an operational amplifier and also requires an additional circuit for correction, and hence, increase of the power consumption cannot be avoided. Also for the correction circuit to be added, it is necessary to secure the accuracy for the correction of the resistance distortion.

### CITATION LIST

### Patent Literature

[PTL 1]
Japanese Patent Laid-Open No. 2017-38135

### SUMMARY

### Technical Problem

Accordingly, the present disclosure provides an electronic circuit that suppresses distortion of a three-terminal resistor.

### Solution to Problem

According to an embodiment, the electronic circuit includes a first resistor and a second resistor. The first resistor has a configuration of a resistor for a voltage between a first terminal and a second terminal thereof, and the first terminal is connected directly or indirectly to an input of the electronic circuit. The second resistor has a configuration of a resistor for a voltage between a first terminal and a second terminal thereof, and the first terminal is connected directly or indirectly to the second terminal of the first resistor, and the second terminal is connected to an output of the electronic circuit. In the electronic circuit, the second terminal of the second resistor is connected directly or indirectly to a third terminal through which a resistance value of the first resistor is varied by a voltage.

The first terminal of the first resistor may be connected to a third terminal through which a resistance value of the second resistor is varied by a voltage.

The electronic circuit may have symmetry in that the electronic circuit has the same configuration even in a case where the first terminal of the first resistor is connected to the output and the second terminal of the second resistor is connected to the input.

The electronic circuit may further include a third resistor having a first terminal, a second terminal, and a third terminal and a fourth resistor having a first terminal, a second terminal, and a third terminal. In a first resistor group including the first resistor and the second resistor and a second resistor group that includes the third resistor and the fourth resistor and has a connection scheme that has symmetry and is different from that of the first resistor group in that the second terminal of the third resistor and the first terminal of the fourth resistor are at least connected directly or indirectly, the first resistor group and the second resistor group may be connected in series or in parallel and the third terminal of any of the resistors belonging to the first resistor group and the second resistor group may be connected to the first terminal or the second terminal of the other resistor of the resistor group to which the relevant resistor belongs.

The electronic circuit may further include a third resistor having a first terminal, a second terminal, and a third terminal, the second terminal being connected to the first terminal of the first resistor, and a fourth resistor having a first terminal, a second terminal, and a third terminal, the first terminal being connected to the second terminal of the second resistor.

The third resistor, the first resistor, the second resistor, and the fourth resistor have symmetry in this order.

In a first resistor group including the third resistor, the first resistor, the second resistor, and the fourth resistor and a second resistor group that is a different resistor group having symmetry, the first resistor group and the second resistor group may be connected in series or in parallel, and the third terminal of any of the resistors belonging to the first resistor group and the second resistor group may be connected to the first terminal or the second terminal of a different resistor of the resistor group to which the relevant resistor belongs.

### BRIEF DESCRIPTION OF DRAWINGS

FIG. 1 is a circuit diagram of an electronic circuit according to an embodiment.

FIG. 2 is a circuit diagram of an electronic circuit according to another embodiment.

FIG. 3 is a circuit diagram of an electronic circuit according to a further embodiment.

FIG. 4 is a circuit diagram of an electronic circuit according to a still further embodiment.

FIG. 5 is a circuit diagram of an electronic circuit according to a yet further embodiment.

FIG. 6 is a circuit diagram of an electronic circuit according to a yet further embodiment.

FIG. 7 is a circuit diagram of an electronic circuit according to a yet further embodiment.

FIG. 8 is a circuit diagram of an electronic circuit according to a yet further embodiment.

FIG. 9 is a circuit diagram of an electronic circuit according to a yet further embodiment.

FIG. 10 is a circuit diagram of an electronic circuit according to a yet further embodiment.

FIG. 11 is a circuit diagram of an electronic circuit according to a yet further embodiment.

FIG. 12 is a circuit diagram of an electronic circuit according to a yet further embodiment.

FIG. 13 is a circuit diagram of an electronic circuit according to a yet further embodiment.

FIG. 14 is a circuit diagram of an electronic circuit according to a yet further embodiment.

FIG. 15 is a circuit diagram of an electronic circuit according to a yet further embodiment.

FIG. 16 is a circuit diagram of an electronic circuit according to a yet further embodiment.

FIG. 17 is a circuit diagram of an electronic circuit according to a yet further embodiment.

FIG. 18 is a circuit diagram of an electronic circuit according to a yet further embodiment.

FIG. 19 is a circuit diagram of an electronic circuit according to a yet further embodiment.

FIG. 20 is a circuit diagram of an electronic circuit according to a yet further embodiment.

FIG. 21 is a circuit diagram of an electronic circuit according to a yet further embodiment.

FIG. 22 is a circuit diagram of an electronic circuit according to a yet further embodiment.

FIG. 23 is a circuit diagram of an electronic circuit according to a yet further embodiment.

FIG. 24 is a circuit diagram of an electronic circuit according to a yet further embodiment.

FIG. 25 is a circuit diagram of an electronic circuit according to a yet further embodiment.

FIG. 26 is a circuit diagram of an electronic circuit according to a yet further embodiment.

FIG. 27 is a circuit diagram of an electronic circuit according to a yet further embodiment.

FIG. 28 is a circuit diagram of an electronic circuit according to a yet further embodiment.

FIG. 29 is a circuit diagram of an electronic circuit according to a yet further embodiment.

FIG. 30 is a circuit diagram of an electronic circuit according to a yet further embodiment.

FIG. 31 is a circuit diagram of an electronic circuit according to a yet further embodiment.

FIG. 32 is a graph depicting a resistance value of an electronic circuit according to an embodiment.

FIG. 33 is a layout diagram of an electronic circuit according to an embodiment.

FIG. 34 is a cross sectional view of the layout of the electronic circuit according to the embodiment.

FIG. 35 is a layout diagram of an electronic circuit according to another embodiment.

FIG. 36 is a layout diagram of an electronic circuit according to a further embodiment.

### DESCRIPTION OF EMBODIMENTS

In the following, embodiments according to the present disclosure are described with reference to the drawings. The drawings are used for description and the shape and the size of the configuration of each portion in an actual apparatus and the ratio in size or the like to that of a different configuration need not be as such depicted in the drawings. Further, since the drawings are given in a simplified form, it is recognized that components necessary for implementation other than those depicted in the drawings are provided appropriately.

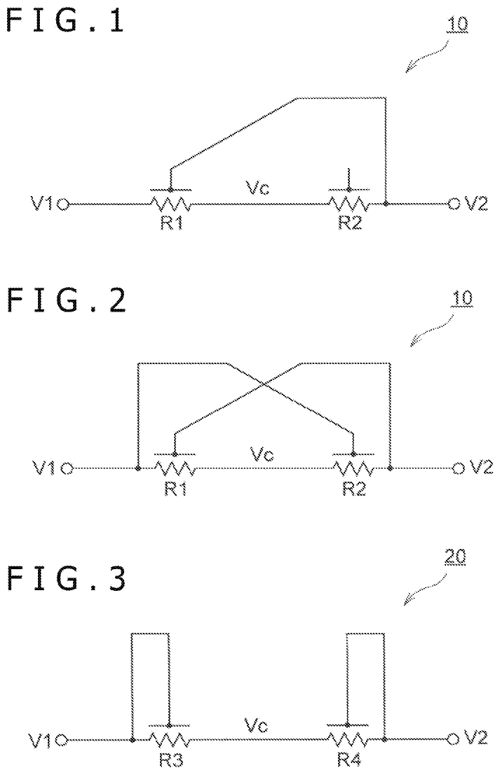

FIG. 1 depicts a circuit diagram of an electronic circuit according to an embodiment. A first resistor network 10 includes a first resistor R1 and a second resistor R2 that are two three-terminal resistors. The three-terminal resistors have a resistance value that changes depending upon the voltage applied to a sub terminal thereof. In the following description, terminals of a three-terminal resistor that are connected as those of the resistor are referred to as a first terminal and a second terminal, and the sub terminal mentioned above is referred to as a third terminal. Although, in the following description, the resistance value of the first resistor R1 is represented as R1, whether R1 represents a circuit element or a resistance value is to be suitably distinguished depending upon the context.

In FIG. 1, the first resistor R1 is connected at the first terminal thereof to the outside and connected at the second terminal thereof in series to the second resistor R2. The second resistor R2 is connected at the first terminal thereof to the second terminal of the first resistor R1 and connected at the second terminal thereof to the outside and also to the third terminal of the first resistor R1. Where the first terminal of the first resistor R1 and the second terminal of the second resistor R2 are connected in any electronic circuit, the first resistor network 10 operates as one resistor.

As depicted in FIG. 1, the first resistor R1 is connected at the third terminal thereof to that one of the terminals of the second resistor R2 connected to the first resistor R1, which is on the opposite side of the terminal to which the first resistor R1 itself is connected, that is, to the terminal of the second resistor R2 that is on the far side. Although, in FIG. 1, no resistor is provided between the first resistor R1 and the second resistor R2, one or multiple other resistors may be provided between the resistors. In other words, the first resistor network 10 in the present embodiment is a circuit according to a resistor network having multiple resistors.

The first resistor network 10 includes, for example, an input terminal and an output terminal and is placed in a circuit such that the terminals are connected between voltages V1 and V2. Thus, the first resistor network 10 functions as a resistor network between the voltage V1 and the voltage V2.

FIG. 2 depicts a circuit diagram of another example of the first resistor network 10 implemented according to the configuration of FIG. 1. The connection of the first resistor R1 is similar to that in the example depicted in FIG. 1. In FIG. 2, the second resistor R2 is further connected at the third terminal thereof to the first terminal of the first resistor R1.

The first resistor network 10 preferably has symmetry such that the structure thereof does not change even if the terminals of the circuit as a whole are replaced as depicted in FIG. 2. The first resistor network 10 having symmetry signifies that it has an equivalent function even if the terminals connected, for example, to the voltages V1 and V2 are replaced. In order to secure this symmetry, it is preferable that the resistance value of the first resistor R1 and the resistance value of the second resistor R2 as well as the resistances of them each have same characteristics. In other words, preferably the same resistance element is used for the first resistor R1 and the second resistor R2.

Similarly as above, the third terminal of the second resistor R2 is connected to the first terminal of the first resistor R1 that is the far terminal as viewed from the second resistor R2. In such a manner, the terminals of the first resistor R1 and the second resistor R2 may be connected in what is generally called a crossed state.

Here, the signal distortion to be generated by resistors with respect to the circuit to which they are connected, in a case where the resistors are connected in such a manner as depicted in FIG. 1 or 2, is calculated.

First, in a case where V1, V2, are respectively applied to the first terminal, the second terminal, and the third terminal of a three-terminal resistor having a resistance value R, the resistance value of the circuit is represented by Expression (1) given below.

$$\begin{matrix}[ Math . 1 ] & \\ R = {R}_{0} ( 1 + k ( \frac{{V}_{1} + {V}_{2}}{2} - {V}_{r} ) ) & ( 1 )\end{matrix}$$

Here, R0 is a resistance value in a state in which the voltage at the third terminal is the middle point of the voltages at the first terminal and the second terminal, and k is a coefficient determined from the effective area and the depletion layer of the material (for example, polysilicon) from which the resistors are formed and typically satisfies k<<1. The term multiplied by k in Expression (1) is the primary distortion of the resistor.

In a case where such a connection scheme as depicted in FIG. 1 is applied, since Vr=V2, the combined resistance value R is represented by such an expression as given below.

$$\begin{matrix}[ Math . 2 ] & \\ R = {R}_{0} ( 1 + k ( \frac{{V}_{1} + {V}_{2}}{2} - {V}_{1} ) ) = {R}_{0} ( 1 + k ( \frac{- {V}_{1} + {V}_{2}}{2} ) ) & ( 2 )\end{matrix}$$

In the meantime, in a case where such a connection scheme as depicted in FIG. 2 is applied, the resistance value is represented by such an expression as given below.

$$\begin{matrix}[ Math . 3 ] & \\ R = \frac{{R}_{0}}{2} ( 1 + k ( \frac{{V}_{1} + {V}_{c}}{2} - {V}_{2} ) ) + \frac{{R}_{0}}{2} ( 1 + k ( \frac{{V}_{c} + {V}_{2}}{2} - {V}_{1} ) ) = {R}_{0} ( 1 + \frac{k}{2} ( {V}_{c} - \frac{{V}_{1} + {V}_{2}}{2} ) ) & ( 3 )\end{matrix}$$

It is to be noted that, as depicted in FIGS. 1 and 2, the voltage between the first resistor R1 and the second resistor R2, that is, the potential at the second terminal of the first resistor R1 and the first terminal of the second resistor R2, is represented by Vc.

Meanwhile, since Vc is represented by dividing V1 and V2 by the ratio in resistance value of the first resistor R1 and the second resistor R2, if Expression (1) is applied to R1 and R2, then the following Expression (4) is satisfied.

$$\begin{matrix}[ Math . 4 ] & \\ {V}_{c} = \frac{{V}_{2} \cdot {R}_{1} + {V}_{1} \cdot {R}_{2}}{{R}_{1} + {R}_{2}} = \frac{\begin{matrix}{V}_{2} \cdot \frac{{R}_{0}}{2} ( 1 + k ( \frac{{V}_{1} + {V}_{c}}{2} - {V}_{2} ) ) + \\ {V}_{1} \cdot \frac{{R}_{0}}{2} ( 1 + k ( \frac{{V}_{2} + {V}_{c}}{2} - {V}_{1} ) )\end{matrix}}{\frac{{R}_{0}}{2} ( 1 + k ( \frac{{V}_{1} + {V}_{c}}{2} - {V}_{2} ) ) + \frac{{R}_{0}}{2} ( 1 + k ( \frac{{V}_{2} + {V}_{c}}{2} - {V}_{1} ) )} & ( 4 )\end{matrix}$$

By solving Expression (4) for Vc, Expression (5) is obtained.

$$\begin{matrix}[ Math . 5 ] & \\ {V}_{c} = \frac{\begin{matrix}- 2 + k ( {V}_{1} + {V}_{2} ) \pm \\ \sqrt{{( 2 - k ( {V}_{1} + {V}_{2} ) )}^{2} - 4 k ( k ( {V}_{1}^{2} + {V}_{2}^{2} - {V}_{1} {V}_{2} ) - ( {V}_{1} + {V}_{2} ) )}\end{matrix}}{2 k} = - \frac{1}{k} + \frac{1}{2} ( {V}_{1} + {V}_{2} ) \pm \sqrt{\frac{1}{{k}^{2}} - \frac{3}{4} {( {V}_{1} - {V}_{2} )}^{2}} & ( 5 )\end{matrix}$$

Here, if a case in which V1=V2 is considered, then since Vc=V1=V2, the double sign in Expression (5) can be determined to be positive. If Vc of Expression (5) is substituted into Expression (3) and approximation is applied since k<<1, then the following expression is obtained for the combined resistance value R.

$$\begin{matrix}[ Math . 6 ] & \\ \begin{matrix}R = {R}_{0} ( 1 + \frac{1}{2} ( - 1 + \sqrt{1 - \frac{3 {k}^{2}}{4} {( {V}_{1} - {V}_{2} )}^{2}} ) ) \\ ≃ {R}_{0} ( 1 - \frac{3 {k}^{2}}{16} {( {V}_{1} - {V}_{2} )}^{2} )\end{matrix} & ( 6 )\end{matrix}$$

From the relation of Expression (6), the distortion by voltage dependency of the resistor is, in Expression (2), first order distortion and is, in Expression (6), second order distortion. In particular, it can be recognized that the first order distortion component of the voltage across the three-terminal resistor is converted into second order distortion by such arrangement of the resistors as depicted in FIG. 2. Further, it can be recognized that, since k<<1, the voltage dependency of the resistor is lower than that in the case of FIG. 1.

Further, Expression (6) is an upward projecting function with respect to the voltage. From this, if a resistor (network) having a downward projecting second order distortion characteristic with respect to the voltage is connected to the resistor, then the influence of the secondary distortion of the resistor with respect to the voltage can be reduced.

As described above, with the first resistor network 10 according to the present embodiment, it is possible to form a resistor having an upward projecting second order characteristic with respect to the voltage.

Now, described is a circuit which is used in combination with the first resistor network 10 depicted in FIG. 2 and cancels a second order distortion characteristic of the resistance value with respect to the voltage.

FIG. 3 is a diagram depicting an example of a second resistor network that suppresses second order distortion caused by a voltage of the first resistor network 10 depicted in FIG. 2. The second resistor network 10 includes a third resistor R3 and a fourth resistor R4.

The first terminal and the third terminal of the third resistor R3 are connected to each other, and the third resistor R3 is connected in series to the fourth resistor R4. The second terminal and the third terminal of the fourth resistor R4 are connected to each other, and the first terminal of the fourth resistor R4 is connected to the second terminal of the third resistor R3.

The combined resistance value R in this case is represented in the following manner.

$$\begin{matrix}[ Math . 7 ] & \\ R = \frac{{R}_{0}}{2} ( 1 + k ( \frac{{V}_{1} + {V}_{c}}{2} - {V}_{1} ) ) + \frac{{R}_{0}}{2} ( 1 + k ( \frac{{V}_{c} + {V}_{2}}{2} - {V}_{2} ) ) = {R}_{0} ( 1 + \frac{k}{2} ( {V}_{c} - \frac{{V}_{1} + {V}_{2}}{2} ) ) & ( 7 )\end{matrix}$$

Further, Vc is represented in the following manner.

$$\begin{matrix}[ Math . 8 ] & \\ {V}_{c} = \frac{{V}_{2} \cdot {R}_{3} + {V}_{1} \cdot {R}_{4}}{{R}_{3} + {R}_{4}} = \frac{\begin{matrix}{V}_{2} \cdot \frac{{R}_{0}}{2} ( 1 + k ( \frac{{V}_{1} + {V}_{c}}{2} - {V}_{1} ) ) + \\ {V}_{1} \cdot \frac{{R}_{0}}{2} ( 1 + k ( \frac{{V}_{2} + {V}_{c}}{2} - {V}_{2} ) )\end{matrix}}{\frac{{R}_{0}}{2} ( 1 + k ( \frac{{V}_{1} + {V}_{c}}{2} - {V}_{1} ) ) + \frac{{R}_{0}}{2} ( 1 + k ( \frac{{V}_{2} + {V}_{c}}{2} - {V}_{2} ) )} & ( 8 )\end{matrix}$$

From the two expressions above, the combined resistance value R is determined in the following manner by performing expression conversion similar to that described above.

$$\begin{matrix}[ Math . 9 ] & \\ \begin{matrix}R = {R}_{0} ( 1 - \frac{1}{2} ( 1 - \sqrt{1 + \frac{{k}^{2}}{4} {( {V}_{1} - {V}_{2} )}^{2}} ) ) \\ ≃ {R}_{0} ( 1 - \frac{{k}^{2}}{16} {( {V}_{1} - {V}_{2} )}^{2} )\end{matrix} & ( 9 )\end{matrix}$$

As can be recognized from this expression, the resistance value of the second resistor network 20 of FIG. 3 has downward projecting second order distortion of the voltage.

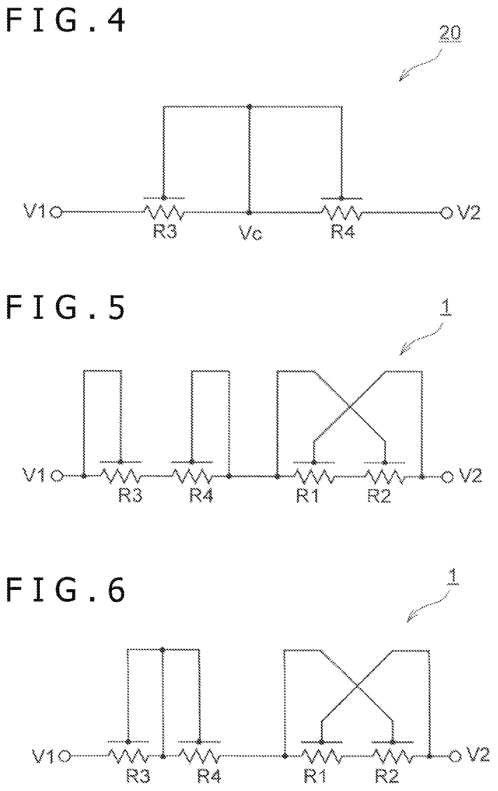

FIG. 4 is a diagram depicting an example of a second resistor network that suppresses second order distortion caused by the voltage of the first resistor network 10 depicted in FIG. 2 and has a configuration different from that depicted in FIG. 3. As in the case of FIG. 3, the second resistor network 10 includes a third resistor R3 and a fourth resistor R4.

The second terminal and the third terminal of the third resistor R3 are connected to each other, and the third resistor R3 is connected in series to the fourth resistor R4. The first terminal and the third terminal of the fourth resistor R4 are connected to each other, and the first terminal of the fourth resistor R4 is connected to the second terminal of the third resistor R3.

The combined resistance value R in this case is represented in the following manner.

$$\begin{matrix}[ Math . 10 ] & \\ R = \frac{{R}_{0}}{2} ( 1 + k ( \frac{{V}_{1} + {V}_{c}}{2} - {V}_{1} ) ) + \frac{{R}_{0}}{2} ( 1 + k ( \frac{{V}_{c} + {V}_{2}}{2} - {V}_{2} ) ) = {R}_{0} ( 1 + \frac{k}{2} ( \frac{{V}_{1} + {V}_{2}}{2} - {V}_{c} ) ) & ( 10 )\end{matrix}$$

Meanwhile, Vc is represented in the following manner.

$$\begin{matrix}[ Math . 11 ] & \\ {V}_{c} = \frac{{V}_{2} \cdot {R}_{3} + {V}_{1} \cdot {R}_{4}}{{R}_{3} + {R}_{4}} = \frac{{V}_{2} \cdot \frac{{R}_{0}}{2} ( 1 + k ( \frac{{V}_{1} + {V}_{c}}{2} - {V}_{c} ) ) + {V}_{1} \frac{{R}_{0}}{2} ( 1 + k ( \frac{{V}_{2} + {V}_{c}}{2} - {V}_{c} ) )}{\frac{{R}_{0}}{2} ( 1 + k ( \frac{{V}_{1} + {V}_{c}}{2} - {V}_{c} ) ) + \frac{{R}_{0}}{2} ( 1 + k ( \frac{{V}_{2} + {V}_{c}}{2} - {V}_{c} ) )} & ( 11 )\end{matrix}$$

From the two expressions above, the combined resistance value R is determined in the following manner by performing expression conversion similar to that described above.

$$\begin{matrix}[ Math . 12 ] & \\ \begin{matrix}R = {R}_{0} ( 1 - \frac{1}{2} ( 1 - \sqrt{1 + \frac{{k}^{2}}{4} {( {V}_{1} - {V}_{2} )}^{2}} ) ) \\ ≃ {R}_{0} ( 1 - \frac{{k}^{2}}{16} {( {V}_{1} - {V}_{2} )}^{2} )\end{matrix} & ( 12 )\end{matrix}$$

As can be recognized from this expression, the resistance value of the second resistor network 20 of FIG. 4 has downward projecting second order distortion of the voltage. In other words, the second resistor network 20 has a characteristic similar to that in the case of FIG. 3.

If the first resistor network 10 depicted in FIG. 2 and the second resistor network 20 depicted in FIG. 3 or 4 are combined, then distortion arising from the second order of the voltage of the resistance value as a whole can be reduced.

In the following, several examples in which four resistance elements are connected in series are described.

FIG. 5 is a diagram depicting an electronic circuit in which the resistor networks according to the embodiments are combined. For example, an electronic circuit 1 is configured such that the first resistor network 10 depicted in FIG. 2 and the second resistor network 20 depicted in FIG. 3 are connected in series.

By such a connection scheme as just described, a resistor can be formed such that the second order distortion by the voltage decreases according to Expression (6) or Expression (9).

FIG. 6 is a diagram depicting an electronic circuit in which the resistor networks according to the embodiments are combined. For example, the electronic circuit 1 is configured such that the first resistor network 10 depicted in FIG. 2 and the second resistor network 20 depicted in FIG. 4 are connected in series.

By such a connection scheme as just described, a resistor can be formed such that the second order distortion by the voltage is reduced according to Expression (6) or Expression (12).

Although the resistor networks are connected in series in FIGS. 5 and 6, the connection of them is not limited to the series connection, and they may otherwise be connected in parallel. In particular, combining the first resistor network 10 and the second resistor network 20 in parallel also makes it possible to suppress the second order distortion of the resistance value arising from the voltage.

Further, several examples in which the resistor networks have symmetry are described. The electronic circuits 1 described below have common points in that

(1) the connection of resistors has symmetry; and
(2) a voltage is applied to the third terminal of at least one resistor (at least two resistors from the symmetry) from a terminal from a far side terminal of the opposite resistor as viewed from the resistor.
The characteristic just described is indicated as a composition of resistors represented, for example, by Expression (2), Expression (6), Expression (9), or Expression (12). The electronic circuit preferably includes both the first resistor network 10 and the second resistor network 20.

It is to be noted that the resistors in the first resistor network 10 have the same characteristic while the resistors in the second resistor network 20 have the same characteristic. On the other hand, the resistors in the first resistor network 10 and the resistors in the second resistor network 20 are not required to have the same characteristic. For example, the resistors in the first resistor network 10 and the resistors in the second resistor network 20 may be combinations having such characteristics that, for example, the upward and downward projections of the second order distortions of the voltage cancel each other.

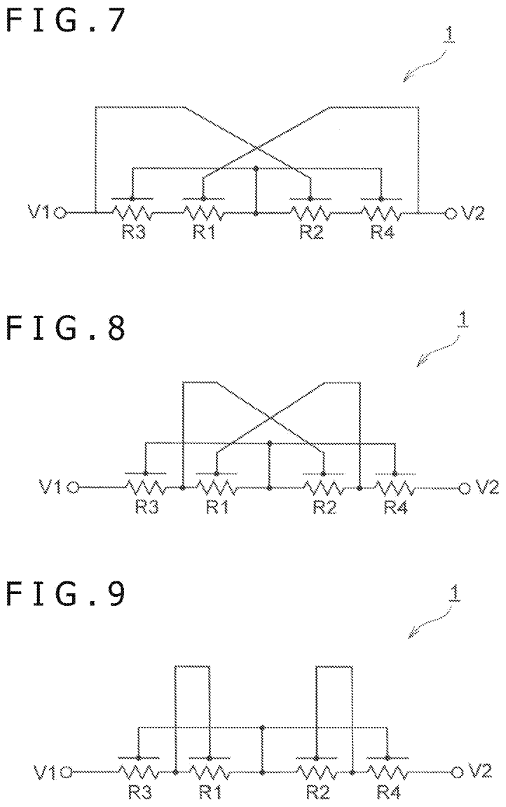

FIG. 7 depicts a connection example of resistors having the symmetry described hereinabove. In the resistors depicted in FIG. 7, the first resistor R1 and the second resistor R2 are connected in crossed connection; the third terminal of the third resistor R3 is connected to the second terminal of the first resistor R1 that is a far terminal as viewed from the third resistor R3; and the third terminal of the fourth resistor R4 is connected to the first terminal of the second resistor R2 that is a far terminal as viewed from the fourth resistor R4.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 4.

FIG. 8 depicts a connection example of resistors having the symmetry described hereinabove. In the resistors depicted in FIG. 8, the first resistor R1 and the second resistor R2 are connected in crossed connection; the third terminal of the third resistor R3 is connected to the second terminal of the first resistor R1 that is on the far side; and the third terminal of the fourth resistor R4 is connected to the first terminal of the second resistor R2 that is on the far side.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 4.

FIG. 9 depicts a connection example of resistors having the symmetry described hereinabove. In the resistors depicted in FIG. 9, the third terminal of the first resistor R1 is connected to the first terminal thereof; the third terminal of the second resistor R2 is connected to the second terminal thereof; the third terminal of the third resistor R3 is connected to the second terminal of the first resistor R1 that is on the far side; and the third terminal of the fourth resistor R4 is connected to the first terminal of the second resistor R2 that is on the far side.

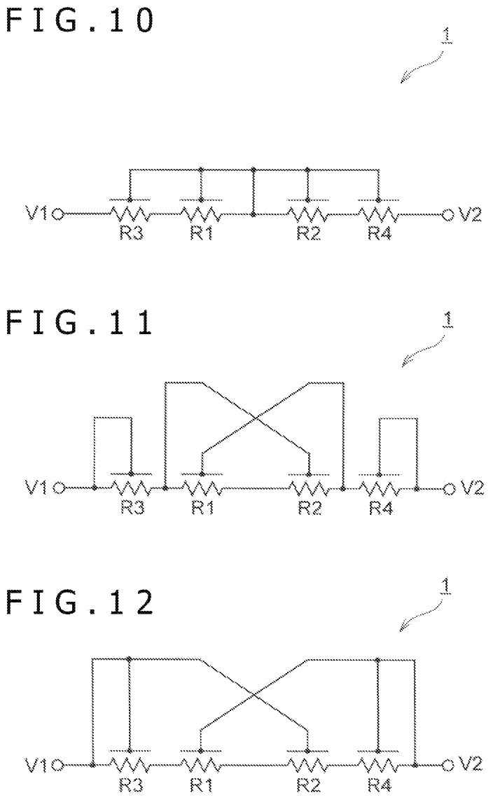

FIG. 10 depicts a connection example of resistors having the symmetry described hereinabove. In the resistors depicted in FIG. 10, the third terminal of the first resistor R1 is connected to the second terminal thereof; the third terminal of the second resistor R2 is connected to the first terminal thereof; the third terminal of the third resistor R3 is connected to the second terminal of the first resistor R1 that is on the far side; and the third terminal of the fourth resistor R4 is connected to the first terminal of the second resistor R2 that is on the far side.

FIG. 11 depicts a connection example of resistors having the symmetry described hereinabove. In the resistors depicted in FIG. 11, the first resistor R1 and the second resistor R2 are connected in crossed connection; the third terminal of the third resistor R3 is connected to the first terminal thereof; and the third terminal of the fourth resistor R4 is connected to the second terminal thereof.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 3.

FIG. 12 depicts a connection example of resistors having the symmetry described hereinabove. In the resistors depicted in FIG. 12, the first resistor R1 and the second resistor R2 are connected in crossed connection with the third resistor R3 and the fourth resistor R4 interposed therebetween; the third terminal of the third resistor R3 is connected to the first terminal thereof; and the third terminal of the fourth resistor R4 is connected to the second terminal thereof.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 3.

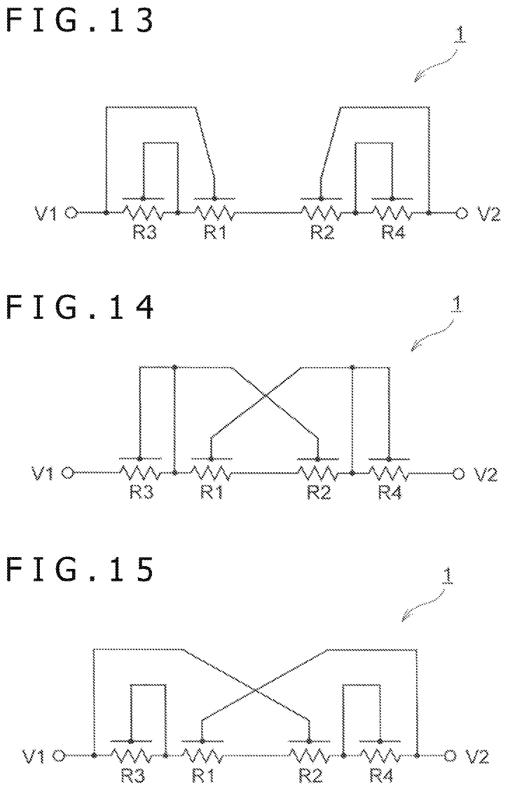

FIG. 13 depicts a connection example of resistors having the symmetry described hereinabove. In the resistors depicted in FIG. 13, the third terminal of the first resistor R1 is connected to the first terminal of the third resistor R3 that is on the far side; the third terminal of the second resistor R2 is connected to the second terminal of the fourth resistor R4 that is on the far side; the third terminal of the third resistor R3 is connected to the second terminal thereof; and the third terminal of the fourth resistor R4 is connected to the first terminal thereof.

FIG. 14 depicts a connection example of resistors having the symmetry described hereinabove. In the resistors depicted in FIG. 14, the first resistor R1 and the second resistor R2 are connected in crossed connection; the third terminal of the third resistor R3 is connected to the second terminal thereof; and the third terminal of the fourth resistor R4 is connected to the first terminal thereof.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 4 with the first resistor R1 and the second resistor R2 interposed therebetween.

FIG. 15 depicts a connection example of resistors having the symmetry described hereinabove. In the resistors depicted in FIG. 15, the first resistor R1 and the second resistor R2 are connected in crossed connection with the third resistor R3 and the fourth resistor R4 interposed therebetween; the third terminal of the third resistor R3 is connected to the second terminal thereof; and the third terminal of the fourth resistor R4 is connected to the first terminal thereof.

The electronic circuit 1 includes, where attention is paid to the first resistor R1 and the second resistor R2, the first resistor network 10 depicted in FIG. 2 and includes, where attention is paid to the third resistor R3 and the fourth resistor R4, the second resistor network 20 depicted in FIG. 4.

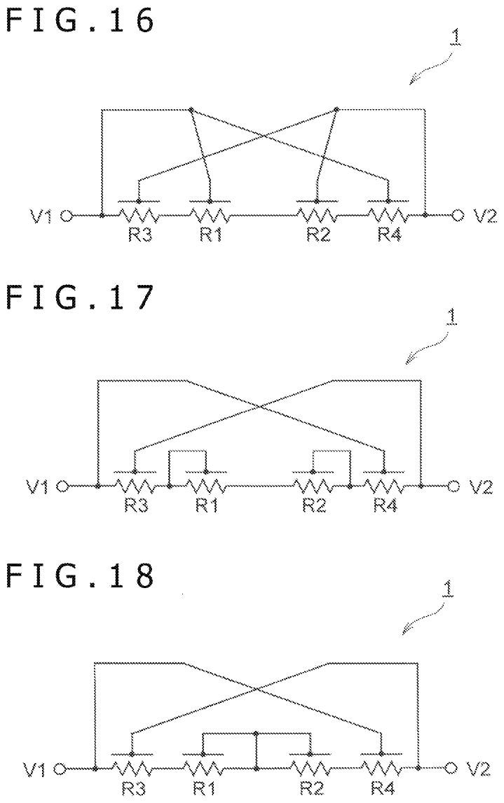

FIG. 16 depicts a connection example of resistors having the symmetry described hereinabove. In the resistors depicted in FIG. 16, the third resistor R3 and the first resistor R1 and the fourth resistor R4 are connected in crossed connection; and the fourth resistor R4 and the second resistor R2 and the third resistor R3 are connected in crossed connection.

The electronic circuit 1 includes, where attention is paid to the first resistor R1 and the second resistor R2, the second resistor network 20 depicted in FIG. 3 and includes, where attention is paid to the third resistor R3 and the fourth resistor R4, the first resistor network 10 depicted in FIG. 2.

FIG. 17 depicts a connection example of resistors having the symmetry described hereinabove. In the resistors depicted in FIG. 17, the third terminal and the first terminal of the first resistor R1 are connected to each other; the third terminal and the second terminal of the second resistor R2 are connected to each other; and the third resistor R3 and the fourth resistor R4 are connected in crossed connection.

The electronic circuit 1 includes, where attention is paid to the first resistor R1 and the second resistor R2, the second resistor network 20 depicted in FIG. 3 and includes, where attention is paid to the third resistor R3 and the fourth resistor R4, the first resistor network 10 depicted in FIG. 2.

FIG. 18 depicts a connection example of resistors having the symmetry described hereinabove. In the resistors depicted in FIG. 18, the third terminal and the second terminal of the first resistor R1 are connected to each other; the third terminal and the first terminal of the second resistor R2 are connected to each other; and the third resistor R3 and the fourth resistor R4 are connected in crossed connection.

The electronic circuit 1 includes, where attention is paid to the first resistor R1 and the second resistor R2, the second resistor network 20 depicted in FIG. 4 and includes, where attention is paid to the third resistor R3 and the fourth resistor R4, the first resistor network 10 depicted in FIG. 2.

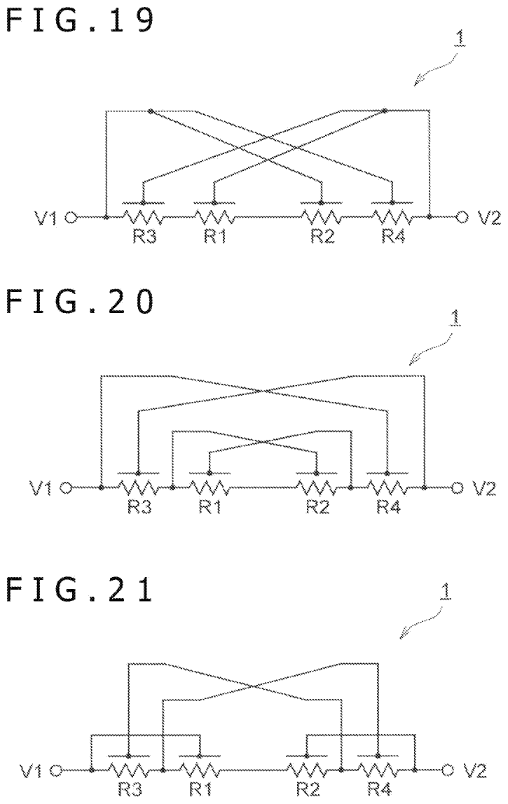

FIG. 19 depicts a connection example of resistors having the symmetry described hereinabove. In the resistors depicted in FIG. 19, the first resistor R1 and the second resistor R2, the first resistor R1 and the fourth resistor R4, the second resistor R2 and the third resistor R3, and the third resistor R3 and the fourth resistor R4 are each connected in crossed connection.

FIG. 20 depicts a connection example of resistors having the symmetry described hereinabove. In the resistors depicted in FIG. 20, the first resistor R1 and the second resistor R2 as well as the third resistor R3 and the fourth resistor R4 are each connected in crossed connection.

FIG. 21 depicts a connection example of resistors having the symmetry described hereinabove. In the resistors depicted in FIG. 21, the third terminal of the first resistor R1 is connected to the first terminal of the third resistor R3 that is on the far side; the third terminal of the second resistor R2 is connected to the second terminal of the fourth resistor R4 that is on the far side; the third terminal of the third resistor R3 is connected to the second terminal of the second resistor R2 that is on the far side; and the third terminal of the fourth resistor R4 is connected to the first terminal of the first resistor R1 that is on the far side.

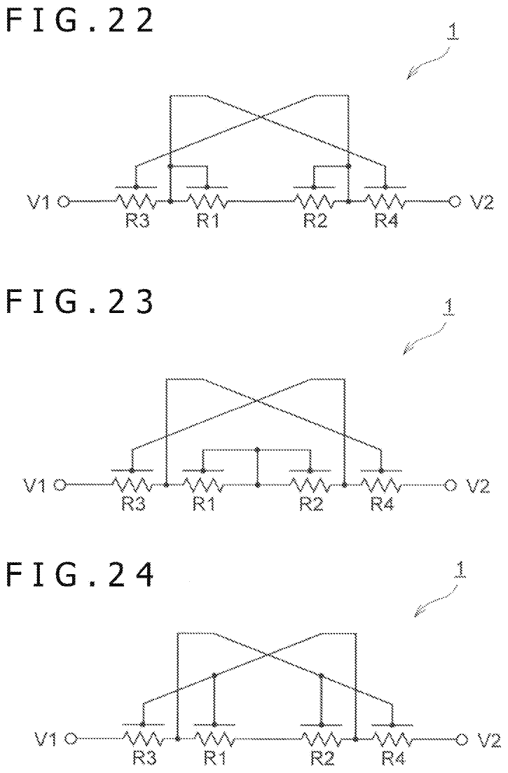

FIG. 22 depicts a connection example of resistors having the symmetry described hereinabove. In the resistors depicted in FIG. 22, the third terminal of the first resistor R1 is connected to the first terminal thereof; the third terminal of the second resistor R2 is connected to the second terminal thereof; the third terminal of the third resistor R3 is connected to the second terminal of the second resistor R2 that is on the far side; and the third terminal of the fourth resistor R4 is connected to the first terminal of the first resistor R1 that is on the far side.

FIG. 23 depicts a connection example of resistors having the symmetry described hereinabove. In the resistors depicted in FIG. 23, the third terminal of the first resistor R1 is connected to the second terminal thereof; the third terminal of the second resistor R2 is connected to the first terminal thereof; the third terminal of the third resistor R3 is connected to the second terminal of the second resistor R2 that is on the far side; and the third terminal of the fourth resistor R4 is connected to the first terminal of the first resistor R1 that is on the far side.

FIG. 24 depicts a connection example of resistors having the symmetry described hereinabove. In the resistors depicted in FIG. 24, the first resistor R1 and the second resistor R2 are connected in crossed connection; the third terminal of the third resistor R3 is connected to the second terminal of the second resistor R2 that is on the far side; and the third terminal of the fourth resistor R4 is connected to the first terminal of the first resistor R1 that is on the far side.

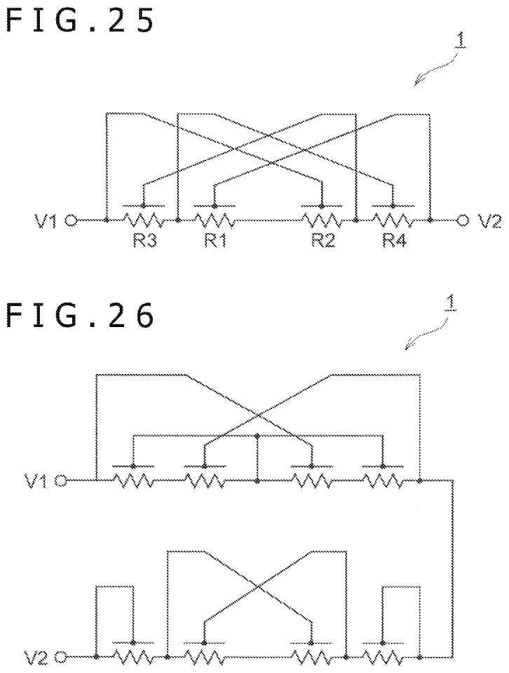

FIG. 25 depicts a connection example of resistors having the symmetry described hereinabove. In the resistors depicted in FIG. 25, the first resistor R1 and the second resistor R2 are connected in crossed connection with the third resistor R3 and the fourth resistor R4 interposed therebetween; the third terminal of the third resistor R3 is connected to the second terminal of the second resistor R2 that is on the far side; and the third terminal of the fourth resistor R4 is connected to the first terminal of the first resistor R1 that is on the far side.

Simple characteristics of the examples described above are described.

If the electronic circuit 1 in each of FIGS. 8, 10, 22, and 23 is examined as a whole, then it has a resistance value that indicates a great amount of change depending upon the voltage and has a downward projecting characteristic. If the electronic circuit 1 in each of FIGS. 17 and 18 is examined as a whole, then it has a resistance value that indicates a great amount of change depending upon the voltage and has an upward projecting characteristic.

Accordingly, if one of the electronic circuits 1 in FIGS. 8, 10, 22, and 23 is selected while one of the electronic circuits 1 in FIGS. 17 and 18 is selected and then the selected circuits are connected in series or in parallel, then the characteristics of the two can be cancelled.

If the electronic circuit 1 in each of FIGS. 7, 9, 13, and 24 is examined as a whole, then it has a resistance value that indicates a small amount of change depending upon the voltage and has a downward projecting characteristic. If the electronic circuit 1 in each of FIGS. 11, 12, 14, and 21 is examined as a whole, then it has a resistance value that indicates a small amount of change depending upon the voltage and has an upward projecting characteristic.

Hence, if one of the electronic circuits 1 in FIGS. 7, 9, 13, and 24 is selected and one of the electronic circuits 1 in FIGS. 11, 12, 14, and 21 is selected and then the selected circuits are connected in series or in parallel, then the characteristics of the two can be cancelled.

It is to be noted that, in any of the cases described above, the resistance value of each resistor may be adjusted appropriately in such a manner as to cancel the distortion.

Two or more of the resistor networks that are formed to have symmetry with use of the four resistance elements described hereinabove may be used in combination. Several examples in which, for example, two such resistor networks as just described are combined are described below.

FIG. 26 depicts a connection example in which resistor groups having the symmetry described above are connected in series. As depicted in FIG. 26, the electronic circuit 1 of FIG. 7 and the electronic circuit 1 of FIG. 11 may be combined to configure a resistor as a new electronic circuit 1.

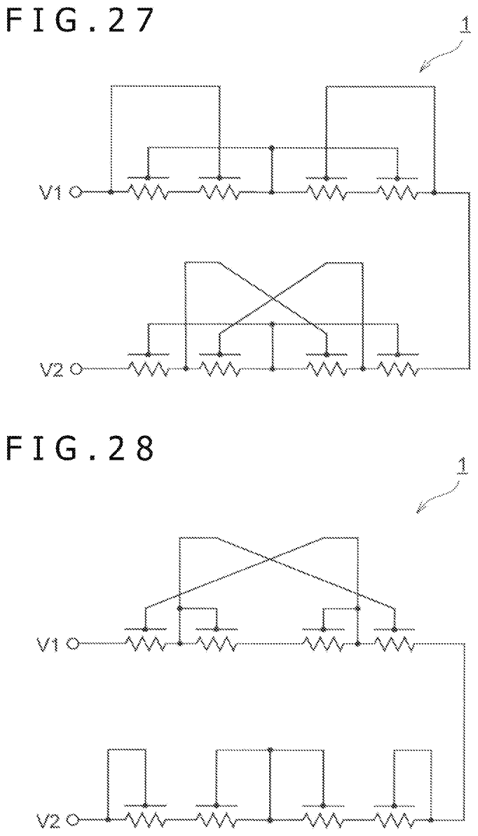

FIG. 27 depicts a connection example in which resistor groups having the symmetry described above are connected in series. As depicted in FIG. 27, the electronic circuit 1 of FIG. 8 and a resistor group including four resistors connected in series and having symmetry may be combined to configure a resistor as a new electronic circuit 1.

The circuit depicted in FIG. 27 is configured such that the input of the circuit of FIG. 8 and the output of a circuit that is a modified form of the circuit of FIG. 9 are connected in series. More particularly, a circuit in which the third terminal of the first resistor R1 in FIG. 9 is connected to the first terminal of the third resistor R3, and the third terminal of the second resistor R2 is connected to the second terminal of the fourth resistor R4 is connected in series to the circuit of FIG. 8.

FIG. 28 depicts a connection example in which resistor groups having the symmetry described hereinabove are connected in series. As depicted in FIG. 28, the electronic circuit 1 of FIG. 22 and a resistor group including four resistors connected in series and having symmetry may be combined to configure a resistor as a new electronic circuit 1.

The circuit depicted in FIG. 28 is configured such that the input of the circuit of FIG. 22 and the output of a circuit that is a modified form of the circuit of FIG. 11 are connected in series. More particularly, the third terminal of the first resistor R1 in FIG. 11 is connected to the second terminal and the third terminal of the second resistor R2 is connected to the first terminal.

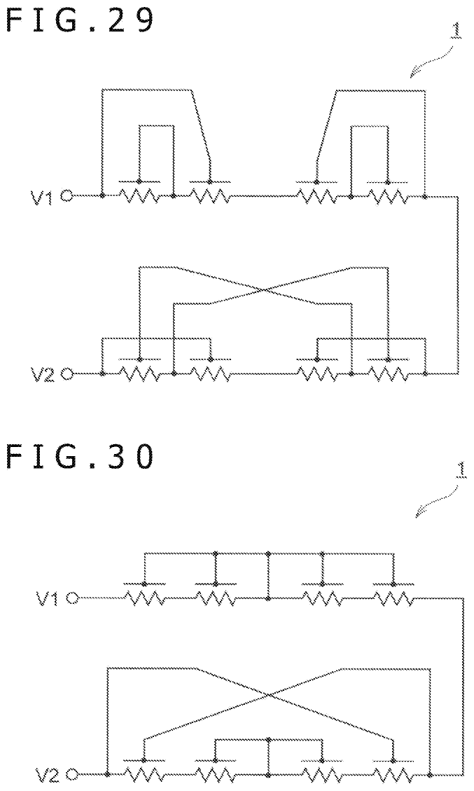

FIG. 29 depicts a connection example in which resistor groups having the symmetry described hereinabove are connected in series. As depicted in FIG. 29, the electronic circuit 1 of FIG. 13 and the electronic circuit 1 of FIG. 21 may be combined to configure a resistor as a new electronic circuit 1.

FIG. 30 depicts a connection example in which resistor groups having the symmetry described hereinabove are connected in series. As depicted in FIG. 30, the electronic circuit 1 of FIG. 10 and the electronic circuit 1 of FIG. 18 may be combined to configure a resistor as a new electronic circuit 1.

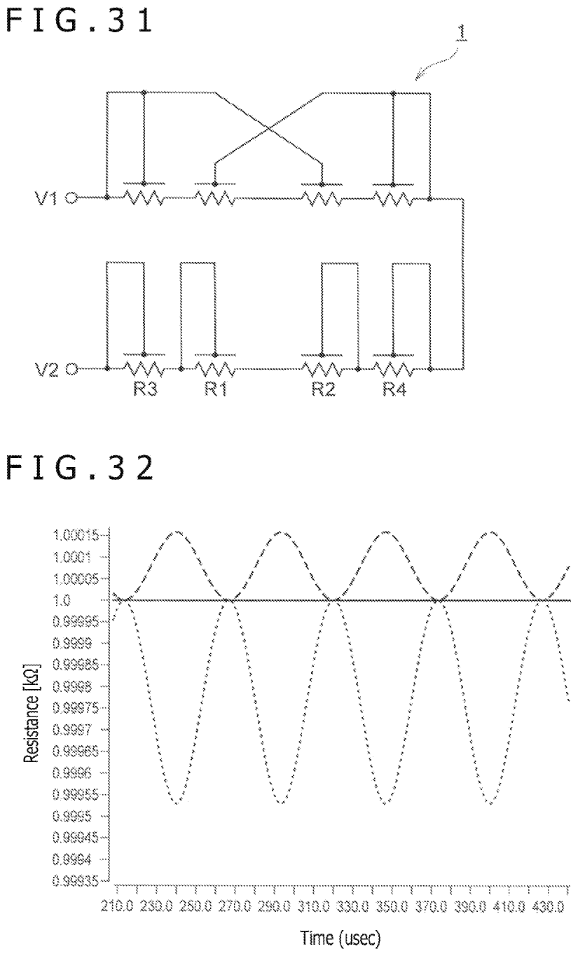

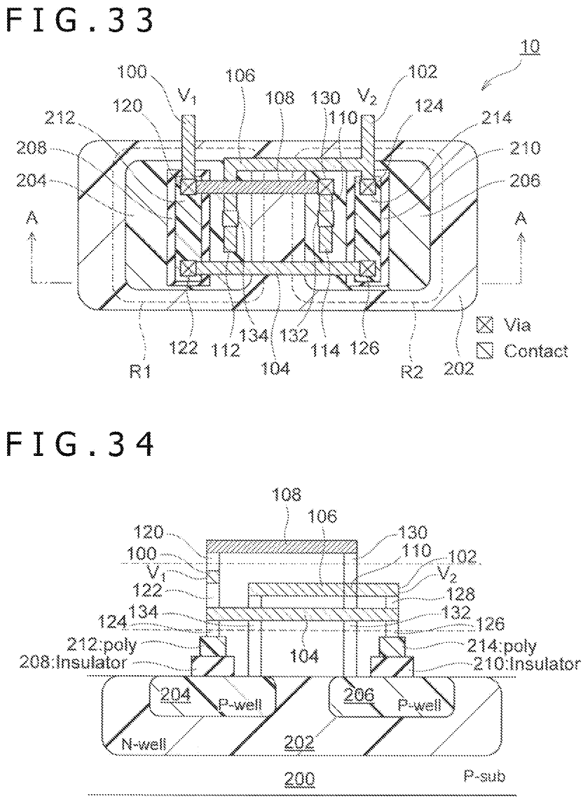

FIG. 31 depicts a connection example in which resistor groups having the symmetry described hereinabove are connected in series. As depicted in FIG. 31, the electronic circuit 1 of FIG. 12 and a resistor group including four resistors connected in series and having symmetry may be combined to configure a resistor as a new electronic circuit 1.

The circuit depicted in FIG. 31 is configured such that the input of the circuit of FIG. 12 and the output of a circuit that is a modified form of the circuit of FIG. 9 are connected in series. More particularly, the third terminal of the third resistor R3 in FIG. 9 is connected to the first terminal, and the third terminal of the fourth resistor R4 is connected to the second terminal.

The combinations described above are indicated as examples, and the other circuits described hereinabove may be connected to each other.

The electronic circuits 1 enumerated above are all capable of suppressing second order distortion of the voltage value to be applied to a sub terminal (third terminal) of a three-terminal resistor. According to such examples as described above, it is possible to reduce a distortion characteristic of the resistor caused by voltage dependency without the necessity for an additional circuit such as a comparator or a voltage generator. Since a correction circuit other than resistance elements is not required, increase of the power consumption arising from addition of such a correction circuit as just described can be suppressed. Further, the resistors are not restricted to those of the same characteristic, the same material, or the like if they have equivalent characteristics.

Such advantageous effects as described above are implemented by arrangement of resistors having symmetry being provided in at least part of the electronic circuit 1. For example, the electronic circuit 1 may have symmetry as a whole as those depicted in FIGS. 7 to 31 or the electronic circuit 1 may include multiple electronic circuits each having symmetry as depicted in FIGS. 5, 6, and 26 to 31. Further, although the number of resistors in the present disclosure is eight in the maximum, this is not restrictive, and an electronic circuit 1 having connection including a greater number of electronic circuits having symmetry may be connected.

Although the resistor groups (resistor networks) in the foregoing description are connected in series, for example, also in the examples of FIGS. 26 to 31, the resistor networks may be connected not in series but in parallel to reduce the distortion.

Further, attention should be paid to the fact that, in any case, in a case where multiple resistor groups having symmetry are provided, any resistor is connected at the third terminal thereof to the first terminal or the second terminal of another resistor to which the resistor itself belongs.

FIG. 32 is a diagram depicting oscillation of the resistance value (quantity that changes depending upon the voltage) of several ones of the electronic circuits 1 as a whole in a case where a sinusoidally oscillating voltage is inputted as a signal thereto. A solid line indicates the resistance value of the electronic circuit 1 depicted in FIG. 6; a dotted line indicates the resistance value of the electronic circuit 1 depicted in FIG. 2; and a broken line indicates a resistance value of the electronic circuit 1 depicted in FIG. 3 or 4.

It can be recognized that, in regard to the resistance value of the electronic circuit 1 depicted in FIG. 6, as can be understood from the graph of FIG. 6, the amount of change that depends upon the voltage can be reduced significantly in comparison with that in a case where two resistors are provided. For example, in an example according to one simulation, in a case where elements having the same voltage and the same resistance value are used, while the amplitude of the dotted line curve is 468.8 mΩ and the amplitude of the broken line curve is 155.8 mΩ, the amplitude (amount of change) of the solid line curve is 667 nΩ that is an amplitude (amount of change) of approximately 1/200,000 to 1/700,000. Further, with the combinations described above, the value of the amplitude (amount of change) can be reduced furthermore.

In such a manner, with the electronic circuit 1 according to the present embodiments, since it is configured such that, to a sub terminal of a three-terminal resistor, at least a voltage at a far side terminal of a different resistor connected in series to the three-terminal resistor is applied, it is possible to correct second order distortion of the resistor arising from variation of the voltage.

Layout examples of the circuit diagram depicted in FIG. 2, which has a basic form of the first resistor network 10 provided in the electronic circuit 1 in the present embodiments, are described.

FIG. 33 is a plan view depicting a layout of the circuit diagram depicted in FIG. 2. For example, the first resistor R1 and the second resistor R2 are resistors formed on a semiconductor substrate.

FIG. 34 is a sectional view taken along line A-A of FIG. 33. It is to be noted that the layouts, cross sections, and so forth described below are examples, and the mode according to the present disclosure is not restricted to them. Further, conduction types described below are described as mere examples, and the conduction types are also not restricted to them.

Both the first resistor R1 and the second resistor R2 may be produced on a semiconductor substrate. For example, the semiconductor substrate is a P-type substrate 200. An N-type well 202 is formed on the semiconductor substrate, and P-type wells 204 and 206 are formed on the N-type well. Resistors are formed on the well regions. For example, the P-type wells 204 and 206 may be metal.

An insulating film 208 is formed on the P-type well region 204, polysilicon 212 is formed on the insulating film 208, and this polysilicon 212 plays a role of a resistor. Similarly, an insulating film 210 is formed on the well 206, polysilicon 214 is formed on the insulating film 210, and this polysilicon 214 functions as a resistor.

Connection of the polysilicon and the well regions to the outside is described.

A lead wire 100 is provided as a terminal to which the voltage V1 is applied, that is, as the input terminal (or the output terminal) described hereinabove. Similarly, a lead wire 102 is provided as a terminal to which the voltage V2 is applied, that is, as the output terminal (or the input terminal) described hereinabove.

A voltage applied to the lead wire 100 is applied to the polysilicon 212 through a via 120 (first terminal). Further, the polysilicon 212 is connected to a lead wire 104 in a different region through a via 122 (second terminal).

The lead wire 104 is connected at the other end portion thereof to the polysilicon 214 through a via 126 (first terminal). The polysilicon 214 is connected to the lead wire 102, that is, to the output terminal, in a different region through a via 124 (second terminal). The resistors connected in series are formed from the polysilicon 212 and the polysilicon 214 in such a manner.

As depicted in FIG. 2, the input terminal and the output terminal are connected to the third terminal of the resistors. This connection is described.

The lead wire 100 is connected to a lead wire 108 different from that described above through the via 100. The lead wire 108 is connected, on the second resistor R2, to an electrode 114 (third terminal) on the well 206 through a via 130, a lead wire 110, and a contact 132. Through this electrode 114, a voltage is applied to the well 206, and the resistance value varies.

Similarly, the lead wire 102 is connected to an electrode 112 (third terminal) through a lead wire 106 and a contact 134 on the first resistor R1. Through this electrode 112, a voltage is applied to the well 204, and the resistance value varies.

In such a manner, the first resistor R1 and the second resistor R2 may be formed as resistors each having a well region on the same semiconductor substrate. Further, by connecting them in such a manner, it is possible to apply the same voltage to the first terminal of the first resistor R1 and the third terminal of the second resistor R2 and apply the same voltage to the second terminal of the second resistor R2 and the third terminal of the first resistor R1.

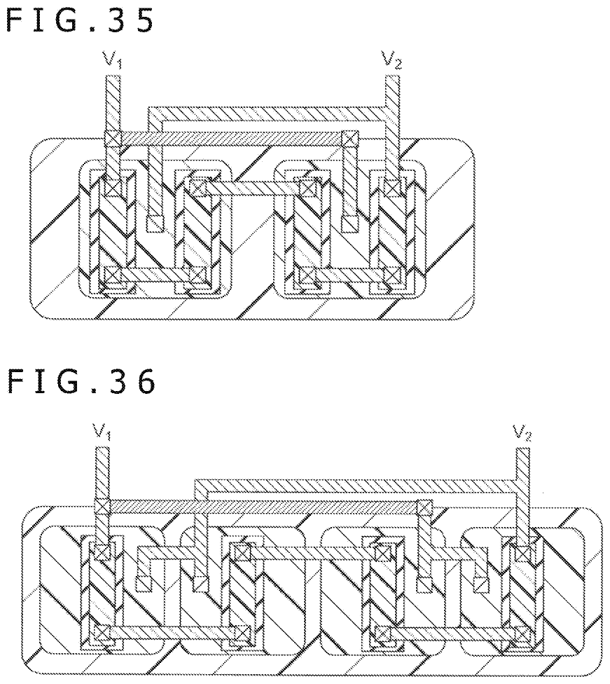

FIGS. 35 and 36 depict different examples on this substrate. As depicted in FIG. 35, the first resistor R1 may be placed in a divided form on the same well. This similarly applies also to the second resistor R2.

As depicted in FIG. 36, the first resistor R1 may be placed in a divided form on different wells. This similarly applies also to the second resistor R2.

The embodiments described may have such modes as described below.

(1)

An electronic circuit including:

a first resistor having a configuration of a resistor for a voltage between a first terminal and a second terminal thereof, the first terminal being connected directly or indirectly to an input of the electronic circuit; and

a second resistor having a configuration of a resistor for a voltage between a first terminal and a second terminal thereof, the first terminal being connected directly or indirectly to the second terminal of the first resistor, the second terminal being connected to an output of the electronic circuit, in which

the second terminal of the second resistor is connected directly or indirectly to a third terminal through which a resistance value of the first resistor is varied by a voltage.

(2)

An electronic circuit in which

the first terminal of the first resistor is connected to a third terminal through which a resistance value of the second resistor is varied by a voltage.

(3)

The electronic circuit according to (1) or (2), in which

the electronic circuit has symmetry in that the electronic circuit has the same configuration even in a case where the first terminal of the first resistor is connected to the output and the second terminal of the second resistor is connected to the input.

(4)

The electronic circuit according to (3), further including:

a third resistor having a first terminal, a second terminal, and a third terminal; and

a fourth resistor having a first terminal, a second terminal, and a third terminal, in which,

in a first resistor group including the first resistor and the second resistor, and

a second resistor group that includes the third resistor and the fourth resistor and has a connection scheme that has symmetry and is different from that of the first resistor group in that the second terminal of the third resistor and the first terminal of the fourth resistor are at least connected,

the first resistor group and the second resistor group are connected in series or in parallel, and

the third terminal of any of the resistors belonging to the first resistor group and the second resistor group is connected to the first terminal or the second terminal of the other resistor of the resistor group to which the relevant resistor belongs.

(5)

The electronic circuit according to any one of (1) to (3), further including:

a third resistor having a first terminal, a second terminal, and a third terminal, the second terminal being connected to the first terminal of the first resistor; and

a fourth resistor having a first terminal, a second terminal, and a third terminal, the first terminal being connected to the second terminal of the second resistor.

(6)

The electronic circuit according to (5), in which

the third resistor, the first resistor, the second resistor, and the fourth resistor have symmetry in this order.

(7)

The electronic circuit according to (6), in which,

in a first resistor group including the third resistor, the first resistor, the second resistor, and the fourth resistor, and

a second resistor group that is a different resistor group having symmetry,

the first resistor group and the second resistor group are connected in series or in parallel, and

the third terminal of any of the resistors belonging to the first resistor group and the second resistor group is connected to the first terminal or the second terminal of a different resistor of the resistor group to which the relevant resistor belongs.

The mode of the present disclosure is not limited to the embodiments described hereinabove and includes various conceivable modifications, and the advantageous effects of the present disclosure are also not restricted to the contents described hereinabove. The components in the embodiments may be applied in a suitable combination. In particular, various kinds of additions, alterations, and partial deletions are possible without departing from the conceptive idea and the scope of the present disclosure derived from the contents defined in the claims and equivalents to them.

### REFERENCE SIGNS LIST

1: Electronic circuit
10: First resistor network
20: Second resistor network
R1, R2, R3, R4: Three-terminal resistor

1. An electronic circuit comprising:
a first resistor having a configuration of a resistor for a voltage between a first terminal and a second terminal thereof, the first terminal being connected directly or indirectly to an input of the electronic circuit; and
a second resistor having a configuration of a resistor for a voltage between a first terminal and a second terminal thereof, the first terminal being connected directly or indirectly to the second terminal of the first resistor, the second terminal being connected to an output of the electronic circuit, wherein
the second terminal of the second resistor is connected directly or indirectly to a third terminal through which a resistance value of the first resistor is varied by a voltage.

2. The electronic circuit according to claim 1, wherein
the first terminal of the first resistor is connected to a third terminal through which a resistance value of the second resistor is varied by a voltage.

3. The electronic circuit according to claim 1, wherein
the electronic circuit has symmetry in that the electronic circuit has a same configuration even in a case where the first terminal of the first resistor is connected to the output and the second terminal of the second resistor is connected to the input.

4. The electronic circuit according to claim 3, further comprising:
a third resistor having a first terminal, a second terminal, and a third terminal; and
a fourth resistor having a first terminal, a second terminal, and a third terminal, wherein,
in a first resistor group including the first resistor and the second resistor, and
a second resistor group that includes the third resistor and the fourth resistor and has a connection scheme that has symmetry and is different from that of the first resistor group in that the second terminal of the third resistor and the first terminal of the fourth resistor are at least connected directly or indirectly,
the first resistor group and the second resistor group are connected in series or in parallel, and
the third terminal of any of the resistors belonging to the first resistor group and the second resistor group is connected to the first terminal or the second terminal of the other resistor of the resistor group to which the relevant resistor belongs.

5. The electronic circuit according to claim 1, further comprising:
a third resistor having a first terminal, a second terminal, and a third terminal, the second terminal being connected to the first terminal of the first resistor; and
a fourth resistor having a first terminal, a second terminal, and a third terminal, the first terminal being connected to the second terminal of the second resistor.

6. The electronic circuit according to claim 5, wherein
the third resistor, the first resistor, the second resistor, and the fourth resistor have symmetry in this order.

7. The electronic circuit according to claim 6, wherein,
in a first resistor group including the third resistor, the first resistor, the second resistor, and the fourth resistor, and
a second resistor group that is a different resistor group having symmetry,
the first resistor group and the second resistor group are connected in series or in parallel, and
the third terminal of any of the resistors belonging to the first resistor group and the second resistor group is connected to the first terminal or the second terminal of a different resistor of the resistor group to which the relevant resistor belongs.
